(19) United States
(12) Patent Application Publication
(10) Pub. No.: US 2026/0337519 A1
(43) Pub. Date: Oct. 29, 2026

(54) CLEANING LIQUID AND METHOD FOR CLEANING SUBSTRATE

(71) Applicant: TOKYO OHKA KOGYO CO., LTD., Kanagawa (JP)

(72) Inventors: Lihong LIU, Kanagawa (JP); Takuya OHHASHI, Kanagawa (JP)

(21) Appl. No.: 19/647,229

(22) Filed: Apr. 14, 2026

Related U.S. Application Data
(60) Provisional application No. 63/795,695, filed on Apr. 28, 2025.

(51) Int. Cl. C11D 1/62; C11D 3/43; G03F 7/42; H10P 70/00

(52) U.S. Cl. CPC C11D 1/62; C11D 3/43; G03F 7/425; H10P 70/27

(57) ABSTRACT

A cleaning liquid that can successfully remove different types of various resist films while suppressing corrosion of a corrosion-prone material such as Cu, Co, or an interlayer insulating film; and a method for cleaning a substrate using the cleaning liquid are provided. The cleaning liquid includes tetraalkylammonium hydroxide (A), a protic polar organic solvent (B), an aprotic polar organic solvent (C), and water (D), the tetraalkylammonium hydroxide (A), the protic polar organic solvent (B), and the water (D) are included in specific ranges, and the cleaning liquid has a pH value of 13 or more.

### BACKGROUND OF THE INVENTION

### Field of the Invention

The present invention relates to a cleaning liquid applicable to removal of various organic films, such as resist films, formed on a substrate, and a method for cleaning a substrate using the cleaning liquid.

### Related Art

Semiconductor devices are formed by laminating metal wiring layers, low-dielectric layers, insulating layers, etc., on a substrate such as a silicon wafer. Such semiconductor devices are manufactured by processing each of the above layers using a lithography method in which an etching process is performed using a resist pattern as a mask.

Various organic films, such as resist films or temporarily laminated films (also referred to as sacrificial films) to be used in the lithography method, are often removed using cleaning liquids in a manufacturing process of the semiconductor devices.

Furthermore, as the semiconductor devices become denser and more integrated, a wiring formation method using a damascene method is sometimes adopted. In such a wiring formation method, metals such as copper, which are prone to corrosion, are used as metal wiring materials that make up the metal wiring layers of the semiconductor devices.

On the other hand, for low dielectric materials (also referred to as ILD materials) that make up the low dielectric layers, ILD materials that are prone to corrosion are often adopted. Therefore, there has been a need to develop a cleaning liquid that does not cause corrosion to these corrosion-prone materials when the substrate is cleaned.

As such a cleaning liquid, a cleaning liquid including a quaternary ammonium hydroxide, a water-soluble organic solvent, water, an inorganic base such as potassium hydroxide, and an imidazole compound having a specific structure serving as an anticorrosive agent has been proposed (see Patent Document 1).
Patent Document 1: Japanese Unexamined Patent Application Publication No. 2011-118101

### SUMMARY OF THE INVENTION

It has been confirmed in Patent Document 1 that the cleaning liquid described in Patent Document 1 can remove one type of a resist film formed using an ArF resist material while suppressing corrosion of a low dielectric material or tungsten. However, when the resist film is removed from a substrate using the cleaning liquid, the resist film may not be successfully removed depending on a type of the resist film.

The present invention has been made in view of such circumstances, and an object thereof is to provide a cleaning liquid that can successfully remove different types of various resist films while suppressing corrosion of a corrosion-prone material such as Cu, Co, or an interlayer insulating film; and a method for cleaning a substrate using the cleaning liquid.

The present inventors have conducted extensive studies to solve the above problem. The present invention has been completed based on findings that the above problem can be solved by making a cleaning liquid including tetraalkylammonium hydroxide (A), a protic polar organic solvent (B), an aprotic polar organic solvent (C), and water (D) contain the tetraalkylammonium hydroxide (A), the protic polar organic solvent (B), the aprotic polar organic solvent (C), and the water in specific ranges and have a pH value of 13 or more. Specifically, the present invention provides the following aspects.

A first aspect of the invention is a cleaning liquid including: tetraalkylammonium hydroxide (A); a protic polar organic solvent (B); an aprotic polar organic solvent (C); and water (D),
the tetraalkylammonium hydroxide (A) being included in a percentage by mass of 0.18 by mass or more and 5% by mass or less relative to the cleaning liquid,
the protic polar organic solvent (B) being included in a percentage by mass of 40% by mass or more and 80% by mass or less relative to the cleaning liquid,
the water (D) being included in a percentage by mass of 1% by mass or more and 30% by mass or less relative to the cleaning liquid, and
the cleaning liquid having a pH value at 20 °C of 13 or more.

A second aspect of the present invention is a method for cleaning a substrate, the method including:
cleaning a post-development residue on the substrate by bringing the substrate into contact with a cleaning liquid in a photolithography process using a photosensitive composition,
the cleaning liquid including: tetraalkylammonium hydroxide (A), a protic polar organic solvent (B), an aprotic polar organic solvent (C), and water (D),
the tetraalkylammonium hydroxide (A) being included in a percentage by mass of 0.1% by mass or more and 5% by mass or less relative to the cleaning liquid,
the protic polar organic solvent (B) being included in a percentage by mass of 40% by mass or more and 80% by mass or less relative to the cleaning liquid,
the water (D) being included in a percentage by mass of 1% by mass or more and 30% by mass or less relative to the cleaning liquid, and
the cleaning liquid having a pH value at 20 °C of 13 or more.

The present invention can provide a cleaning liquid that can successfully remove different types of various resist films while suppressing corrosion of a corrosion-prone material such as Cu, Co, or an interlayer insulating film; and a method for cleaning a substrate using the cleaning liquid.

### DETAILED DESCRIPTION OF THE INVENTION

### <<Cleaning Liquid>>

A cleaning liquid includes tetraalkylammonium hydroxide (A), a protic polar organic solvent (B), an aprotic polar organic solvent (C), and water (D).

A percentage of a mass of the tetraalkylammonium hydroxide (A) is 0.1% by mass or more and 5% by mass or less relative to a mass of the cleaning liquid.

A percentage of a mass of the protic polar organic solvent (B) is 40% by mass or more and 80% by mass or less relative to a mass of the cleaning liquid.

A percentage of a mass of the water (D) is 18 by mass or more and 30% by mass or less relative to a mass of the cleaning liquid.

The cleaning liquid has a pH value at 20 °C of 13 or more.

The cleaning liquid can successfully remove various organic films, such as a resist film and is less likely to cause corrosion of a corrosion-prone material such as Cu, Co, or an interlayer insulating film. The cleaning liquid can be suitably used as a cleaning liquid for cleaning a substrate in a manufacturing process of a semiconductor device. Therefore, examples of the substrate include a semiconductor substrate such as a silicon substrate, a substrate produced by applying various processes or treatments to the semiconductor substrate, etc.

The cleaning liquid can be particularly suitably used for cleaning a post-development residue on a substrate in a photolithography process using a photosensitive composition. For the above reason, the cleaning liquid is suitable for cleaning a substrate with the surface having at least one bare and corrosion-prone material selected from the group consisting of Cu, Co, a silicon-containing antireflection film, SiN, TiN, and an interlayer insulating film.

A material of the interlayer insulating film is appropriately selected from known materials that have been used to form the interlayer insulating film. The material of the interlayer insulating film is typically a low dielectric material, a so-called low-k material. Examples of the low dielectric material include a methyl silsesquioxane (MSQ)-based material, a hydroxy silsesquioxane (HSQ)-based material, etc.

Essential or optional components to be included in the cleaning liquid will be described.

### <Tetraalkylammonium Hydroxide (A)>

Tetraalkylammonium hydroxide (A) is not particularly limited. Various tetraalkylammonium hydroxides which have been conventionally formulated into a cleaning liquid for cleaning a semiconductor substrate can be employed as the tetraalkylammonium hydroxide (A).

As the tetraalkylammonium hydroxide (A), a compound represented by Formula (A1) below can be suitably used:

(N⁺R¹R²R³)OH⁻ (A1)

in which R¹, R², and R³ are each independently an alkyl group having 3 or more and 5 or less carbon atoms;

Examples of the alkyl group having 3 or more and 5 or less carbon atoms for R¹, R², and R³ include an n-propyl group, an iso-propyl group, an n-butyl group, an iso-butyl group, a sec-butyl group, a tert-butyl group, an n-pentyl group, etc.

Specific suitable examples of the tetraalkylammonium hydroxide (A) include tetra-n-propylammonium hydroxide, tetraisopropyl ammonium hydroxide, tetra-n-butylammonium hydroxide, tetra-n-pentylammonium hydroxide, etc. Among these, tetra-n-butylammonium hydroxide is preferred.

The cleaning liquid may include one type of the tetraalkylammonium hydroxide (A) alone or two or more thereof may be used in combination.

A percentage of a mass of the compound represented by Formula (A1) is preferably 80% by mass or more, more preferably 90% by mass or more, further preferably 95% by mass or more, and particularly preferably 100% by mass relative to a mass of the tetraalkylammonium hydroxide (A).

A percentage of a mass of the tetraalkylammonium hydroxide (A) is 0.1% by mass or more and 5% by mass or less relative to a mass of the cleaning liquid. A lower limit of the percentage of the mass of the tetraalkylammonium hydroxide (A) may be 0.15% by mass or more, 0.2% by mass or more, or 0.5% by mass or more relative to the mass of the cleaning liquid. An upper limit of the percentage of the mass of the tetraalkylammonium hydroxide (A) may be 4.5% by mass or less, 4% by mass or less, 3% by mass or less relative to the mass of the cleaning liquid.

### <Protic Polar Organic Solvent (B)>

The cleaning liquid includes a combination of a protic polar organic solvent (B) and an aprotic polar organic solvent (C). The cleaning liquid including the combination of the protic polar organic solvent (B) and the aprotic polar organic solvent (C) can successfully remove various organic films.

Various protic polar organic solvents which have been conventionally formulated into a cleaning liquid for cleaning a semiconductor substrate can be employed as the protic polar organic solvent (B). The protic polar organic solvent (B) is preferably an alcoholic solvent having an alcoholic hydroxy group. The alcoholic solvent is preferably an alkane monool such as methanol or ethanol, a glycol, or a glycol monoether, more preferably a glycol or a glycol monoether, and further preferably a glycol monoether.

Specific examples of the glycol monoether include ethylene glycol monomethyl ether, ethylene glycol monoethyl ether, ethylene glycol monopropyl ether, ethylene glycol monobutyl ether, propylene glycol monomethyl ether (PGME), propylene glycol monoethyl ether, propylene glycol monopropyl ether, propylene glycol monobutyl ether, diethylene glycol monomethyl ether (MDG), diethylene glycol monoethyl ether (EDG), diethylene glycol monopropyl ether, diethylene glycol monobutyl ether (BDG), etc.

Among these, diethylene glycol monomethyl ether (MDG), diethylene glycol monoethyl ether (EDG), diethylene glycol monopropyl ether, or diethylene glycol monobutyl ether (BDG) is preferred and diethylene glycol monobutyl ether (BDG) is more preferred from the viewpoints of water solubility, organic film removal performance, inflammability, etc.

A percentage of a mass of the protic polar organic solvent (B) is 40% by mass or more and 80% by mass or less relative to a mass of the cleaning liquid. The percentage of the mass of protic polar organic solvent (B) is preferably 42% by mass or more and 75% by mass or less, more preferably 45% by mass or more and 70% by mass or less, and further preferably 50% by mass or more and 60% by mass or less relative to the mass of the cleaning liquid.

The cleaning liquid may include one type of the protic polar organic solvent (B) alone or two or more thereof may be used in combination.

<Aprotic polar organic solvent (B)>

Various aprotic polar organic solvents which have been conventionally formulated into a cleaning liquid for cleaning a semiconductor substrate can be employed as the aprotic polar organic solvent (C).

Suitable examples of the aprotic polar organic solvent (C) include a sulfoxide such as dimethyl sulfoxide (DMSO); a sulfone such as tetramethylene sulfone; an amide such as N,N-dimethylformamide, N-methylformamide, N,N-dimethylacetamide (DMAc), N-methylacetamide, or N,N-diethylacetamide; a lactam such as N-methyl-2-pyrrolidone or N-ethyl-2-pyrrolidone; a lactone such as β-propiolactone, γ-butyrolactone, γ-valerolactone, δ-valerolactone, γ-caprolactone, or ε-caprolactone; an imidazolidinone such as 1, 3-dimethyl-2-imidazolidinone (DMI), 1,3-diethyl-2-imidazolidinone, 1,3-diisopropyl-2-imidazolidinone, etc.

A percentage of a mass of the aprotic polar organic solvent (C) relative to a mass of the cleaning liquid is not particularly limited unless the desired effect is impaired. The percentage of the mass of the aprotic polar organic solvent (C) is preferably 18 by mass or more and 30% by mass or less, more preferably 2% by mass or more and 25% by mass or less, and further preferably 5% by mass or more and 20% by mass or less relative to the mass of the cleaning liquid.

The cleaning liquid may include one type of the aprotic polar organic solvent (C) alone or two or more thereof may be used in combination.

### <Water (D)>

The cleaning liquid includes water (D). Inclusion of the water (D) in the cleaning liquid allows a water-soluble component to be successfully removed when a substrate is cleaned. A percentage of a mass of the water (D) is 1% by mass or more and 30% by mass or less relative to a mass of the cleaning liquid. The percentage of the mass of the water (D) is preferably 5% by mass or more and 27% by mass or less and more preferably 108 by mass or more and 278 by mass or less relative to the mass of the cleaning liquid.

### <Other Components>

The cleaning liquid may include another component other than the tetraalkylammonium hydroxide (A), the protic polar organic solvent (B), the aprotic polar organic solvent (C), or the water (D), unless the desired effect is impaired. Examples of the other component include an anticorrosive agent, a surfactant, an antifoaming agent, a pH-adjusting agent, etc.

Even if the cleaning liquid does not include an anticorrosive agent, however, the cleaning liquid can be used to successfully remove an organic film on a substrate while suppressing corrosion of a material such as Cu, Co, a silicon-containing antireflective film, SiN, TiN, or an interlayer insulating film. Therefore, the cleaning liquid may or may not include an anticorrosive agent.

### <<Method for Producing Cleaning Liquid>

A cleaning liquid is prepared by uniformly mixing the above-described components in predetermined amounts. Note that, as mentioned above, a pH of the cleaning liquid at 20 °C is 13 or higher. If the pH of the liquid obtained by mixing the components is less than 13 at 20 °C, the pH of the cleaning liquid may be adjusted by adding a small amount of tetraalkylammonium hydroxide (A) or a base other than tetraalkylammonium hydroxide (A) when the cleaning liquid is prepared.

### <<Method for Cleaning Substrate>>

A method for cleaning a substrate is a method including cleaning a post-development residue on the substrate by bringing the substrate into contact with a cleaning liquid in a photolithography process using a photosensitive composition. The above-described cleaning liquid is used as a cleaning liquid.

Cleaning of the substrate with the cleaning liquid is performed in a routine manner. Specifically, the substrate is cleaned by bringing the cleaning liquid into contact with the substrate using, for example, an immersion method, a paddle method, or a spray method. When the spray method is employed, the substrate may be rotated.

A period of time for which the substrate is brought into contact with the cleaning liquid is not particularly limited, as long as the substrate can be cleaned well. Typically, the period of time for which the substrate is brought into contact with the cleaning liquid is preferably 0.1 minutes or more and 10.0 minutes or less and more preferably 0.25 minutes or more and 3.0 minutes or less.

A temperature of the cleaning liquid is not particularly limited as long as the substrate can be cleaned well. Typically, the temperature of the cleaning liquid is preferably 25 °C or more and 70 °C or less and more preferably 40 °C or more and 60 °C or less.

As mentioned above, the present inventors provide (1) to (8) below.
(1) A cleaning liquid including: tetraalkylammonium hydroxide (A); a protic polar organic solvent (B); an aprotic polar organic solvent (C); and water (D),
   the tetraalkylammonium hydroxide (A) being included in a percentage by mass of 0.1% by mass or more and 5% by mass or less relative to the cleaning liquid,
   the protic polar organic solvent (B) being included in a percentage by mass of 40% by mass or more and 80% by mass or less relative to the cleaning liquid,
   the water (D) being included in a percentage by mass of 1% by mass or more and 30% by mass or less relative to the cleaning liquid, and
   the cleaning liquid having a pH value at 20 °C of 13 or more.
(2) The cleaning liquid according to (1), in which the aprotic polar organic solvent (C) is included in a percentage by mass of 1% by mass or more and 30% by mass or less relative to the cleaning liquid.
(3) The cleaning liquid according to (1) or (2), in which the tetraalkylammonium hydroxide (A) is a compound represented by Formula (A1) below:

(N⁺R¹R²R³)OH⁻ (A1)

in which R¹, R², and R³ are each independently an alkyl group having 3 or more and 5 or less carbon atoms.
(4) The cleaning liquid according to any one of (1) to (3), in which the cleaning liquid is for use in cleaning of a post-development residue on a substrate in a photolithography process using a photosensitive composition.
(5) The cleaning liquid according to (4), in which the substrate has a surface having an exposed element composed of at least one material selected from the group consisting of Cu, Co, a silicon-containing antireflection film, SiN, TiN, and an interlayer insulating film.
(6) A method for cleaning a substrate, the method including
   cleaning a post-development residue on the substrate by bringing the substrate into contact with a cleaning liquid in a photolithography process using a photosensitive composition,
   the cleaning liquid including: tetraalkylammonium hydroxide (A), a protic polar organic solvent (B), an aprotic polar organic solvent (C), and water (D),
   the tetraalkylammonium hydroxide (A) being included in a percentage by mass of 0.1% by mass or more and 58 by mass or less relative to the cleaning liquid,
   the protic polar organic solvent (B) being included in a percentage by mass of 40% by mass or more and 80% by mass or less relative to the cleaning liquid,
   the water (D) being included in a percentage by mass of 1% by mass or more and 30% by mass or less relative to the cleaning liquid, and
   the cleaning liquid having a pH value at 20 °C of 13 or more.
(7) The method according to (6), in which the aprotic polar organic solvent (C) is included in a percentage by mass of 1% by mass or more and 30% by mass or less relative to the cleaning liquid.
(8) The method according to (6) or (7), in which the tetraalkylammonium hydroxide (A) is a compound represented by Formula (A1) below:

(N⁺R¹R²R³)OH⁻ (A1)
in which R¹, R², and R³ are each independently an alkyl group having 3 or more and 5 or less carbon atoms.

### EXAMPLES

Examples of the present invention are illustrated, and the present invention is described in more detail. The present invention is not limited to Examples in any way.

### Examples 1 to 7 and Comparative Examples 1 to 15

According to compositions shown in Tables 1 to 3, components shown in Tables 1 to 3 were uniformly mixed to obtain cleaning liquids of Examples 1 to 7 and Comparative Examples 1 to 15. Each of the resulting cleaning liquids was evaluated for photoresist releasability and corrosion resistance according to the below-described methods. Note that, for Comparative Examples 3 to 9, only the corrosion resistance of Co was evaluated. Also, Comparative Examples 3 to 9 were conducted without evaluating for resist releasability due to corrosion of Co.

A1, A2, and A′1 to A′9, shown in Tables 1 to 3, are as follows.

### (Tetraalkylammonium Hydroxide (A))

A1: Tetrabutylammonium hydroxide
A2: Tetramethylammonium hydroxide
   (Other bases (A′))
A′1:2-(2-Aminoethylamino)ethanol
A′2: 2-Aminoethanol
A′3: Diethylenetriamine
A′4: Monoisopropylamine
A′5: Diethanolamine
A′6: 2-Amino-2-methyl-1-propanol
A′7: Triethanolamine
A′8: 3-Amino-1-propanol
A′9: 2-(2-Aminoethoxy)ethanol

### <Resist Releasability>

A silicon substrate with a patterned resist film was immersed in a cleaning liquid at 58 °C for 0.1 to 1.5 minutes to release the resist film. The silicon substrate was pulled up from the cleaning liquid, and then the surface thereof was observed under a microscope to check whether the resist film was completely removed. When the resist film was completely removed, it was determined as “A”, and when the resist film was not completely removed, it was determined as “B”. The following TOK-PR-T1 to TOK-PR-T3 were used as the patterned resist films.
TOK-PR-T1: First negative type photoresist (manufactured by TOKYO OHKA KOGYO CO., LTD.)
TOK-PR-T2: Second negative type photoresist (manufactured by TOKYO OHKA KOGYO CO., LTD.)
TOK-PR-T3: Third negative type photoresist (manufactured by TOKYO OHKA KOGYO CO., LTD.)

### <Evaluation of Corrosion Resistance>

A silicon substrate with a thin film composed of an ILD material, Cu, or Co was immersed in a cleaning liquid at 58 °C for 30 minutes. The silicon substrate was pulled up from the cleaning liquid, and then the thickness of the thin film on a surface of the silicon substrate was measured to evaluate for corrosion of the ILD material, the Cu, or the Co. The thickness of the thin film composed of Cu or Co was measured using an X-ray fluorescence (XRF) analyzer. For the thin film composed of the ILD material, an ellipsometer was used for measurement. When a decrease in the thickness of the thin film was 30 Å or less, it was determined as “A” (no corrosion). When a decrease in the thickness of the thin film was more than 30 Å, it was determined as “B” (corrosion).

TABLE 1

| | | | | | | | | Comparative | |
|---|---|---|---|---|---|---|---|---|---|
| | | Example | | | | | | Example | |
| | | 1 | 2 | 3 | 4 | 5 | 6 | 1 | 2 |
| Tetraalkylammonium | TBAH | 3.00 | 2.00 | 1.50 | 1.00 | 0.50 | 0.25 | 2.50 | — |
| hydroxide (A) | TMAH | — | — | — | — | — | — | — | 2.50 |
| (parts by mass) | | | | | | | | | |
| Protic polar organic | BDG | 57.00 | 58.00 | 58.50 | 59.00 | 59.50 | 59.75 | — | — |
| solvent (B) | | | | | | | | | |
| (parts by mass) | | | | | | | | | |
| Aprotic polar organic | DMSO | 15.00 | 15.00 | 15.00 | 15.00 | 15.00 | 15.00 | — | — |
| solvent (C) | | | | | | | | | |
| (parts by mass) | | | | | | | | | |

| Water (D) (parts by mass) | | 25.00 | 25.00 | 25.00 | 25.00 | 25.00 | 25.00 | 97.50 | 97.50 |
|---|---|---|---|---|---|---|---|---|---|
| pH (20 °C) | | >13.5 | >13.5 | >13.5 | >13.5 | >13.5 | >13.5 | 13.30 | 12.90 |
| Photoresist | TOK-PR-T1 | A | A | A | A | A | A | B | B |
| releasability | TOK-PR-T2 | A | A | A | A | A | A | B | B |
| | TOK-PR-T3 | A | A | A | A | A | A | B | B |
| Corrosion | ILD | A | A | A | A | A | A | B | B |
| resistance | Cu | A | A | A | A | A | A | B | B |
| | Co | A | A | A | A | A | A | B | B |

TABLE 2

| | | Example | Comparative Example | | | | | | |
|---|---|---|---|---|---|---|---|---|---|
| | | 7 | 3 | 4 | 5 | 6 | 7 | 8 | 9 |
| Tetraalkylammonium | A1 | 5.00 | — | — | — | — | — | — | — |
| hydroxide (A) | | | | | | | | | |
| (parts by mass) | | | | | | | | | |
| Another base (A′) | A′1 | — | 5.00 | — | — | — | — | — | — |
| (parts by mass) | A′2 | — | — | 5.00 | — | — | — | — | — |
| | A′3 | — | — | — | 5.00 | — | — | — | — |
| | A′4 | — | — | — | — | 5.00 | — | — | — |
| | A′5 | — | — | — | — | — | 5.00 | — | — |
| | A′6 | — | — | — | — | — | — | 5.00 | — |
| | A′7 | — | — | — | — | — | — | — | 5.00 |
| Protic polar organic | BDG | 56.00 | 56.00 | 56.00 | 56.00 | 56.00 | 56.00 | 56.00 | 56.00 |
| solvent (B) | | | | | | | | | |
| (parts by mass) | | | | | | | | | |
| Aprotic polar organic | DMSO | 14.00 | 14.00 | 14.00 | 14.00 | 14.00 | 14.00 | 14.00 | 14.00 |
| solvent (C) | | | | | | | | | |
| (parts by mass) | | | | | | | | | |

| Water (D) (parts by mass) | | 25.00 | 25.00 | 25.00 | 25.00 | 25.00 | 25.00 | 97.50 | 97.50 |
|---|---|---|---|---|---|---|---|---|---|
| pH (20 °C) | | >13.5 | 12.20 | 12.70 | 12.20 | 12.20 | 11.46 | 12.02 | 10.40 |
| Photoresist | TOK-PR-T1 | A | — | — | — | — | — | — | — |
| releasability | TOK-PR-T2 | A | — | — | — | — | — | — | — |
| | TOK-PR-T3 | A | — | — | — | — | — | — | — |

| | | | | | | | | | |
|---|---|---|---|---|---|---|---|---|---|
| Corrosion resistance | Co | A | B | B | B | B | B | B | B |

TABLE 3

| | | Example | Comparative Example | | | | | |
|---|---|---|---|---|---|---|---|---|
| | | 3 | 10 | 11 | 12 | 13 | 14 | 15 |
| Tetraalkylammonium | A1 | 1.50 | — | — | — | — | — | — |
| hydroxide (A) | | | | | | | | |
| (parts by mass) | | | | | | | | |
| Another base (A′) | A′1 | — | 5.00 | — | — | 5.00 | — | — |
| (parts by mass) | A′8 | — | — | 5.00 | — | — | 5.00 | — |
| | A′9 | — | — | — | 5.00 | — | — | 5.00 |
| Protic polar organic | BDG | 58.50 | 55.00 | 55.00 | 55.00 | 55.00 | 55.00 | 55.00 |
| solvent (B) | | | | | | | | |
| (parts by mass) | | | | | | | | |
| Aprotic polar organic | DMSO | 15.00 | 15.00 | 15.00 | 15.00 | 15.00 | 15.00 | 15.00 |
| solvent (C) | | | | | | | | |
| (parts by mass) | | | | | | | | |

| Water (D) (parts by mass) | | 25.00 | 25.00 | 25.00 | 25.00 | 25.00 | 25.00 | 97.50 |
|---|---|---|---|---|---|---|---|---|
| pH (20 °C) | | >13.5 | 12.10 | 12.50 | 11.40 | 11.40 | 11.80 | 11.20 |
| Photoresist | TOK-PR-T1 | A | A | A | B | A | B | A |
| releasability | TOK-PR-T2 | A | B | B | B | B | B | B |
| | TOK-PR-T3 | A | A | A | A | A | A | A |

| Corrosion | ILD | A | B | A | A | A | A | A |
|---|---|---|---|---|---|---|---|---|
| resistance | Cu | A | A | A | A | A | A | A |
| | Co | A | B | A | A | B | A | A |

According to Tables 1 to 3, the cleaning liquids of Examples each including tetraalkylammonium hydroxide (A), a protic polar organic solvent (B), an aprotic polar organic solvent (C), and water (D) in contents that fall within the aforementioned range and having a pH value at 20 °C of 13 or higher can be used to successfully remove different types of various resist films from a substrate while suppressing corrosion of a corrosion-prone material such as Cu, Co, or an interlayer insulating film.

What is claimed is:

1. A cleaning liquid comprising:
tetraalkylammonium hydroxide (A); a protic polar organic solvent (B); an aprotic polar organic solvent (C); and water (D),
the tetraalkylammonium hydroxide (A) being comprised in a percentage by mass of 0.1% by mass or more and 5% by mass or less relative to the cleaning liquid,
the protic polar organic solvent (B) being comprised in a percentage by mass of 40% by mass or more and 80% by mass or less relative to the cleaning liquid,
the water (D) being comprised in a percentage by mass of 1% by mass or more and 30% by mass or less relative to the cleaning liquid, and
the cleaning liquid having a pH value at 20 °C of 13 or more.

2. The cleaning liquid according to claim 1, wherein the aprotic polar organic solvent (C) is comprised in a percentage by mass of 18 by mass or more and 30% by mass or less relative to the cleaning liquid.

3. The cleaning liquid according to claim 1, wherein the tetraalkylammonium hydroxide (A) is a compound represented by Formula (A1) below:
(N⁺R¹R²R³)OH⁻ (A1)
wherein R¹, R², and R³ are each independently an alkyl group having 3 or more and 5 or less carbon atoms.

4. The cleaning liquid according to claim 1, wherein the cleaning liquid is for use in cleaning of a post-development residue on a substrate in a photolithography process using a photosensitive composition.

5. The cleaning liquid according to claim 4, wherein the substrate has a surface having an exposed element composed of at least one material selected from the group consisting of Cu, Co, a silicon-containing antireflection film, SiN, TiN, and an interlayer insulating film.

6. A method for cleaning a substrate, the method comprising
cleaning a post-development residue on the substrate by bringing the substrate into contact with a cleaning liquid in a photolithography process using a photosensitive composition,
the cleaning liquid comprising: tetraalkylammonium hydroxide (A), a protic polar organic solvent (B), an aprotic polar organic solvent (C), and water (D),
the tetraalkylammonium hydroxide (A) being included in a percentage by mass of 0.1% by mass or more and 5% by mass or less relative to the cleaning liquid,
the protic polar organic solvent (B) being included in a percentage by mass of 40% by mass or more and 80% by mass or less relative to the cleaning liquid,
the water (D) being included in a percentage by mass of 1% by mass or more and 30% by mass or less relative to the cleaning liquid, and
the cleaning liquid having a pH value at 20 °C of 13 or more.

7. The method according to claim 6, wherein the aprotic polar organic solvent (C) is comprised in a percentage by mass of 1% by mass or more and 30% by mass or less relative to the cleaning liquid.

8. The method according to claim 6, wherein the tetraalkylammonium hydroxide (A) is a compound represented by Formula (A1) below:
(N⁺R¹R²R³)OH⁻ (A1)
wherein R¹, R², and R³ are each independently an alkyl group having 3 or more and 5 or less carbon atoms.
